(19) United States
(12) Patent Application Publication
(10) Pub. No.: US 2015/0155028 A1
(43) Pub. Date: Jun. 4, 2015

(54) MEMORY, MEMORY SYSTEM INCLUDING THE MEMORY AND METHOD FOR OPERATING THE MEMORY SYSTEM

(71) Applicant: SK hynix Inc., Gyeonggi-do (KR)

(72) Inventor: Hyun-Woo LEE, Gyeonggi-do (KR)

(21) Appl. No.: 14/303,257

(22) Filed: Jun. 12, 2014

(30) Foreign Application Priority Data
Dec. 4, 2013 (KR) 10-2013-0149734

(51) Int. Cl. G11C 11/406

(52) U.S. Cl. CPC G11C 11/40615

(57) ABSTRACT

A memory system includes a memory controller suitable for applying a refresh command and a refresh operation times information that represents the number of times that refresh operations are to be performed to a memory device, and the memory device suitable for performing a refresh operation as many times as the refresh operation times information represents in response to the refresh command.

### CROSS-REFERENCE TO RELATED APPLICATIONS

The present application claims priority of Korean Patent Application No 10-2013-0149734, filed on Dec. 4, 2013, which is incorporated herein by reference in its entirety.

### BACKGROUND

1. Field

Exemplary embodiments of the present invention generally relate to a memory and a memory system including the memory, and more particularly, to a refresh technology of a memory.

2. Description of the Related Art

Each of the memory cells of a memory device includes a transistor, which serves as a switch and capacitor that stores charges or data. The logic level of a data, which is either “high” having a logic value 1 or “low” having a logic value 0, is determined by charges in the capacitor of a memory cell, that is, according to whether the terminal voltage of the capacitor is high or low.

The data is stored in the form of charges accumulated in the capacitor. Therefore, in principle, no power is consumed. However, since the initial amount of charges stored in the capacitor may be reduced due to leakage current caused by PN bonding of a metal-oxide semiconductor “MOS” transistor, the data may be lost. To prevent the loss of the data the data of the memory cell is read before it is lost and the memory cell is recharged thus keeping the amount of charges based on the read information. This operation has to be performed iteratively and periodically for the memory cell to retain the data. The operation of recharging the memory cell is called a refresh operation.

The refresh operation is performed whenever a refresh command is applied from a memory controller to a memory device. The memory controller applies the refresh command to the memory device at a predetermined time in consideration of the data retention time of the memory device. For example, when a memory device has a data retention time of 64 ms and all of the memory cells in the inside of the memory device are to be refreshed, the refresh command is applied 8000 times. That is, the memory controller applies the refresh command to the memory device 8000 times for 64 ms.

The wait time of the memory controller during the time period while the refresh command is applied from the memory controller to the memory device, becomes a major factor for decreased operation performance of the memory device. Therefore, development of technology capable of preventing the deterioration in the performance of a memory device caused by a refresh operation is needed.

### SUMMARY

An embodiment of the present invention is directed to a technology that may minimize deterioration in the performance of a memory device caused by a refresh operation.

In accordance with an embodiment of the present invention, a memory system may include a memory controller suitable for applying a refresh command and a refresh operation times information that represents the number of times a refresh operation is to be performed to a memory device, and the memory device suitable for performing a refresh operation as many times as the refresh operation times information that represents in response to the refresh command.

In accordance with another embodiment of the present invention, a method for operating a memory system includes applying a refresh command and a refresh operation times information that represents the number of times that a refresh operation is to be performed from a memory controller to a memory device, and performing a refresh operation as many times as the refresh operation times information represents in the memory device.

In accordance with yet another embodiment of the present invention, a memory device may include a decoder suitable for decoding input signals to generate an internal refresh command signal and a refresh operation times code, a refresh signal generator suitable for enabling a refresh signal as many times as the refresh operation times code represents in response to the internal refresh command signal and the refresh operation times code, and a refresh controller suitable for controlling rows of a cell array to be sequentially refreshed when the refresh signal is enabled.

### BRIEF DESCRIPTION OF THE DRAWINGS

FIG. 1 illustrates a memory system 100 in accordance with an embodiment of the present invention.

FIG. 2 illustrates a method for operating the memory system 100 shown in FIG. 1.

FIG. 3 is a block view illustrating a memory device 110 shown in FIG. 1.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the description of the embodiments of the present invention, known structures that are not related to the points of the present invention may be omitted. Also, throughout the disclosure, like reference numerals refer to like parts throughout the various figures and embodiments of the present invention. It is also noted that in this specification “enable” and any variation thereof means “activate” and/or “make operational”. In addition, a singular form may include a plural form as long as it is not specifically mentioned in a sentence.

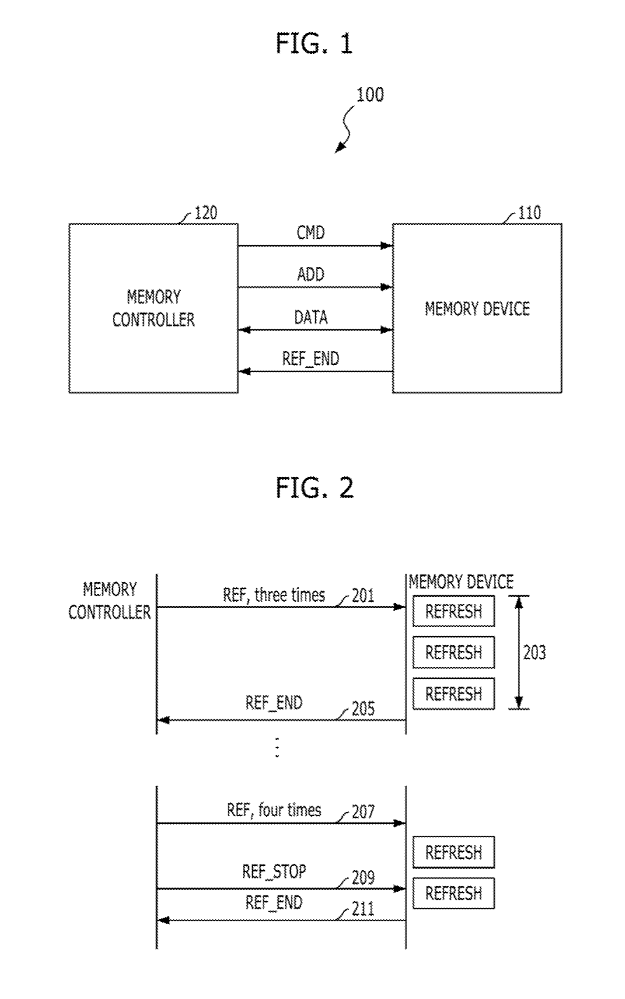

FIG. 1 illustrates a memory system 100 in accordance with an embodiment of the present invention.

Referring to FIG. 1, the memory system 100 includes a memory device 110 and a memory controller 120.

The memory controller 120 controls the operation of the memory device 110 by applying a command CMD and an address ADD. The memory controller 120 may transfer and receive data to and from the memory device 110 during a read operation and/or a write operation. The operations that the memory controller 120 commands the memory device 110 to perform include an active operation, a precharge operation, a read operation, a write operation, a refresh operation and so on. The command CMD may include a plurality of signals, such as a chip selection signal CSb, a row address strobe signal RASb, a column address strobe signal CASb, and a write enable signal WEb. The address ADD may include multi-bit signals. Additionally, the data transferred and received between the memory device 110 and the memory controller 120 may be multi-bit data. According to an embodiment of the present invention, during a refresh operation, the memory controller 120 not only applies a refresh command to the memory device 110 but also notifies the memory device 110 of how many times the memory device 110 has to perform the refresh operation. This will be described in detail below.

The memory device 110 may perform the operation commanded by the memory controller 120. Particularly, when the memory controller 120 commands the memory device 110 to perform a refresh operation, the memory device 110 performs the refresh operation as many times as the memory controller 120 commands, and when all of the refresh operations are performed, the memory device 110 may notify the memory controller 120 of the end of the refresh operations. The enabling of a refresh end signal REF_END transferred from the memory device 110 to the memory controller 120 may signify that the memory device 110 completed all the refresh operations. Upon receipt of the refresh end signal REF_END, the memory controller 120 may recognize that the memory device 110 completed all the commanded refresh operations, and command a subsequent operation.

FIG. 2 illustrates a method for operating the memory system 100 shown in FIG. 1. Since exemplary embodiments of the present invention describe the refresh operation, FIG. 2 shows an operation related to the refresh operation.

Referring to FIG. 2, at a moment “201”, the memory controller 120 notifies the memory device 110 of a refresh command REF and the number of times a refresh operation is to be performed. The refresh command REF may be a combination of the signals CSb, RASb, CASb, and WEb that constitute the command CMD that is transferred from the memory controller 120 to the memory device 110. The number of times the refresh operation is to be performed (refresh operation times information) may be applied using a portion of the address ADD. Table 1 exemplarily shows a combination of the signals CSb, RASb, CASb, and WEb that constitute the command CMD and a combination of addresses A<0>, A<1> and A<10> that represents the number of times the refresh operation is to be performed and the suspension of a refresh operation,

TABLE 1

| CSb | RASb | CASb | WEb | A<0> | A<1> | A<10> | Meaning |
|---|---|---|---|---|---|---|---|
| L | L | L | H | L | L | L | Perform a refresh operation |
| | | | | | | | once. Enable IREF. |
| | | | | | | | CODE<0:2> = 1 |
| L | L | L | H | H | L | L | Perform a refresh operation |
| | | | | | | | twice. Enable IREF. |
| | | | | | | | CODE<0:2> = 2 |
| L | L | L | H | L | H | L | Perform a refresh operation |
| | | | | | | | three times. Enable IREF. |
| | | | | | | | CODE<0:2> = 3 |
| L | L | L | H | H | H | L | Perform a refresh operation |
| | | | | | | | four times. Enable IREF. |
| | | | | | | | CODE<0:2> = 4 |
| L | L | L | H | Don't′ | Don't′ | H | Stop refresh operation. |
| | | | | care | care | | Enable ICMD_STOP |

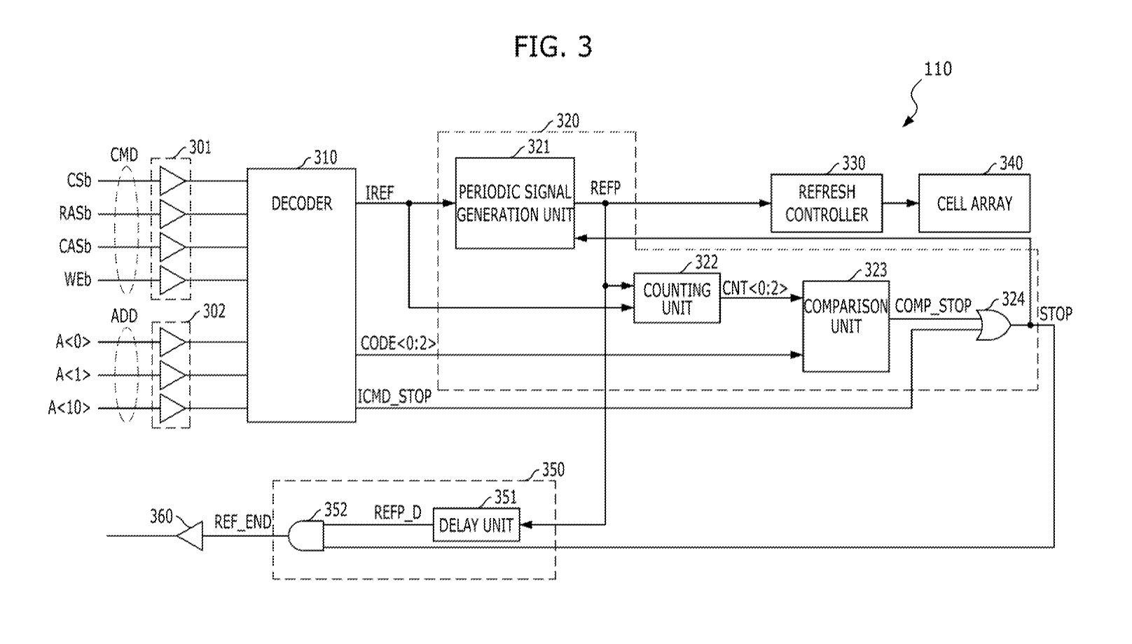

Table 1 illustrates that when the command signals CSb, RASb, CASb, and WEb are L, L, L, and H, respectively, the signals denote a refresh command REF. Also, it may be seen from Table 1 that a combination of a 0^{th} address A<0> and a first address A<1> signifies the number of times the refresh operation is to be performed. If a 10^{th} address A<10> has a “H” level when the refresh command REF is applied, it means to stop the refresh operation. The combinations shown in Table 1 are only illustrative and they do not restrict the scope of the prevent invention, and it is obvious to those skilled in the art that another combination of other signals may transfer a refresh command and information signifying the number of times the refresh operation is to be performed from the memory controller 120 to the memory device 110. The internal signals “IREF”, “CODE<0:2>” and “ICMD_STOP” on the right part of Table 1, are generated in the inside of the memory device 110. They will be described below with reference to FIG. 3.

Referring back to FIG. 2, in response to the refresh command REF and the number of times the refresh operation is to be performed that are applied to the memory device 110 at the moment “201”, which is three times in the drawing, the memory device 110 may perform the refresh operation three times during a section “203”. At a moment “205” when performance of the refresh operation three times is completed, the refresh end signal REF_END notifying the completion of the refresh operation may be enabled and transferred from the memory device 110 to the memory controller 120.

From the moment “201” when the memory controller 120 commands the memory device 110 to perform a refresh operation to the moment “205” when the memory controller 120 is notified by the memory device 110 of the completion of the refresh operation, the memory controller 120 may request the memory device 110 to perform no operation. Meanwhile, from the moment “205” when the refresh operation is completed to a moment “207” when the next refresh command REF is to be applied, the memory controller 120 may command the memory device 110 to perform a desired operation, such as an active operation, a read operation, or a write operation.

At the moment “207”, the memory controller 120 may transfer the refresh command REF and the number of times the refresh operation is to be performed, which is four times in the drawing, to the memory device 110. The memory device 110 may perform a refresh operation in response to the refresh command REF and the number of times the refresh operation is to be performed. While the memory device 110 performs the second refresh operation, which is a moment “209”, the memory controller 120 may apply a refresh operation stop command REF_STOP, which is a command to stop the refresh operation. The memory device 110, which was performing the second refresh operation, then may perform the second refresh operation and omit the third and fourth refresh operations in response to the refresh operation stop command REF_STOP, which the memory controller 120 received at the moment “209”. Then, a refresh end signal REF_END notifying the completion of the refresh operation may be enabled and transferred from the memory device 110 to the memory controller 120 at a moment “211” when the second refresh operation is completed.

Referring to the embodiment of FIGS. 2 and 3, the memory controller 120 applies not only the refresh command REF but also the number of times the refresh operation is to be performed to the memory device 110. Therefore, it is possible to perform the refresh operation several times by applying the refresh command REF once. In this manner, time taken for applying the refresh command REF several times may be saved. Additionally since the memory device 110 notifies the memory controller 1.20 of the completion of the refresh operation when the refresh operation is completed, the time that the memory controller 120 waits for the completion of the refresh operation in the memory device 110 may be minimized.

FIG. 3 is a block view illustrating the memory device 110 shown in FIG. 1. Since features of the embodiments of the present invention describe a refresh operation, FIG. 3 shows the structures of the memory device 110 related to a refresh operation.

Referring to FIG. 3, the memory device 110 may include a command receiving unit 301, an address receiving unit 302, a decoder 310, a refresh signal generator 320, a refresh controller 330, a cell array 340, an end signal generator 350, and a transfer circuit 360.

The command receiving unit 301 may receive a command CMD transferred from the memory controller 120. As described above, the command CMD may include a chip selection signal CSb, a row address strobe signal RASb, a column address strobe signal CASb, and a write enable signal WEb.

The address receiving unit 302 may receive an address ADD transferred from the memory controller 120. FIG. 3 shows the addresses A<0>, A<1> and A<10> related to a refresh operation, however the address ADD may include many address signals other than the 0^{th} address A<0>, the first address A<1>, and the 10^{th} address A<10> that are illustrated in FIG. 3.

The decoder 310 may receive the comand signals CSb, RASb, CASb, and WEb and the addresses A<0>, A<1> and A<10>, and generate an internal refresh command signal IREF, a refresh operation times code CODE<0:2>, and an internal refresh operation stop command signal ICMD_STOP. The internal refresh command signal IREF may be a signal for initiating a refresh operation in the memory device 110. The refresh operation times code CODE<0:2> may be a binary code representing the number of times the refresh operation is to be performed in the memory device 110. Additionally, the internal refresh operation stop command signal ICMD STOP may be a signal for controlling the memory device 110 to stop performing a refresh operation. The operation of the decoder 310 may be easily understood with reference to Table 1, since the conditions for the generation of the signals TREF, CODE<0:2> and ICMD_STOP are described in Table 1.

In response to the internal refresh command signal TREF and the refresh operation times code CODE<0:2>, the refresh signal generator 320 may enable a refresh signal REFP as many times as the refresh operation times code CODE<0:2> represents, For example, when the internal refresh command signal TREF is enabled and the refresh operation times code CODE<0:2> has value of 3, the refresh signal generator 320 may enable the refresh signal REFP three times. Meanwhile, when the internal refresh operation stop command signal ICMD_STOP is enabled, the refresh signal generator 320 does not enable the refresh signal REFP anymore.

The refresh signal generator 320 may include a periodic signal generation unit 321, a counting unit 322, a comparison unit 323, and a stop signal generation unit 324. The periodic signal generation unit 321 may periodically enable the refresh signal REFP from a moment when the internal refresh command signal TREF is enabled to a moment when a stop signal STOP is enabled. When the stop signal STOP is enabled in the middle of the refresh signal REFP being enabled, the enabling of the refresh signal REFP that is already enabled is performed normally, and the refresh signal REFP is controlled to no longer be enabled. The period at which the periodic signal generation unit 321 enables the refresh signal REFP may be controlled based on the time taken for the memory device 110 to perform the refresh operation. The counting unit 322 may count the number of times that the refresh signal REFP is enabled and generate a counting code CNT<0:2>. Meanwhile, the counting code CNT<0:2> may be initialized to “0” in response to the enabling of the internal refresh command signal IREF. The comparison unit 323 may compare the counting code CNT<0:2> with the refresh operation times code CODE<0:2> and enable a preliminary stop signal COMP STOP when the values of the two codes CNT<0:2> and CODE<0:2> are the same. The stop signal generation unit 324 may enable the stop signal STOP when at least one of the preliminary stop signal COMP_STOP and the internal refresh operation stop command signal ICMD_STOP is enabled. The stop signal STOP may be enabled when the refresh signal REFP is enabled as many times as the value of the refresh operation times code CODE<0:2> or when the internal refresh operation stop command signal ICMD_STOP is enabled.

The refresh controller 330 may control the rows in the inside of the cell array 340 to be sequentially refreshed whenever the refresh signal REFP is enabled. For example, if the refresh controller 330 activates an N^{th} row e.g., a word line, while the refresh signal REFP is enabled, the refresh controller 330 may activate an (N+1)^{th} row when the next refresh signal REFP is enabled.

The end signal generator 350 may generate a refresh end signal REF_END that represents the completion of a refresh operation performed in the memory device 110. The end signal generator 350 may include a delay unit 351 and an enabling unit 352. The delay unit 351 may delay the refresh signal REFP by generating a delayed refresh signal REFP_D. The delay value of the delay unit 351 may be set to be the same as the time taken for the memory device 110 to perform a refresh operation once. The enabling unit 352 may enable to the refresh end signal REF_END when both of the stop signal STOP and the delayed refresh signal REFP_D are enabled. Therefore, the refresh end signal REF_END may be a signal that is enabled after the stop signal STOP is enabled and the refresh operation is completed.

The transfer circuit 360 may transfer the refresh end signal REF_END to the memory controller 120. Although FIG. 3 shows the refresh end signal REF_END is transferred to the memory controller 120 through an independent line, it is obvious to those skilled in the art that the refresh end signal REF_END is transferred through a line that is not used during the refresh operation among the multiple lines between the memory device 110 and the memory controller 120. For example, the refresh end signal REF_END may be transferred through a data line between the memory device 110 and the memory controller 120.

Therefore, according to an embodiment of the present invention, deterioration in the performance of a memory device caused by a refresh operation may be minimized.

While the present invention has been described with respect to specific embodiments, it will be apparent to those skilled in the art that various changes and modifications may be made without departing from the spirit and scope of the invention as defined in the following claims.

What is claimed:

1. A memory system, comprising:
a memory controller suitable for applying a refresh command and refresh operation times information that represents a number of times refresh operations are to be performed, to a memory device; and
the memory device suitable for performing refresh operations as many times as the refresh operation times information represents, in response to the refresh command.

2. The memory system of claim 1, wherein the memory device notifies the memory controller of a completion of the refresh operations, after the refresh operations are performed as many times as the refresh operation times information represents.

3. The memory system of claim wherein when the memory controller applies a refresh operation stop command to the memory device,
the memory device ignores the refresh operation times information and terminates the refresh operations while completing the performance of a current refresh operation.

4. The memory system of claim 1, wherein the refresh command and the refresh operation times information are applied from the memory controller to the memory device by using a combination of command signals and address signals.

5. The memory system of claim 2, wherein the memory controller applies no command to the memory device from a moment when the memory controller applies the refresh command to the memory device to a moment when the memory controller is notified of the completion of the refresh operations by the memory device.

6. The memory system of claim 1, wherein the memory device includes:
a decoder suitable for receiving at least one command signal and at least one address signal to generate an internal refresh command signal and a refresh operation times code;
a refresh signal generator suitable for activating a refresh signal as many times as the refresh operation times code represents in response to the internal refresh command signal and the refresh operation times code; and
a refresh controller suitable for controlling rows of a cell array to be sequentially refreshed whenever the refresh signal is activated.

7. The memory system of claim 6, wherein the memory device further includes:
an end signal generator suitable for generating a refresh end signal representing that the refresh operations of the memory device are performed as many times as the refresh operation times code represents; and
a transfer circuit suitable for transferring the refresh nd signal to the memory controller.

8. The memory system of claim 6, wherein the decoder further generates an internal refresh operation stop command signal, and the refresh signal generator does not activate the refresh signal while the internal refresh operation stop command signal s activated.

9. A method for operating a memory system, comprising:
applying a refresh command and refresh operation times information that represents the number of times refresh operations are to be performed, from a memory controller to a memory device; and
performing refresh operations as many times as the refresh operation times information represents in the memory device.

10. The method of claim 9, further comprising:
transferring information representing a completion of the refresh operations from the memory device to the memory controller, after the performing of the refresh operations is completed.

11. The method of claim 9, wherein when a refresh operation stop command signal is applied from the memory controller to the memory device during the refresh operations of the memory device, the memory device ignores the refresh operation times information and terminates the refresh operations while completing the performance of a current refresh operation.

12. A memory device, comprising:
a decoder suitable for decoding input signals to generate an internal refresh command signal and a refresh operation times code;
a refresh signal generator suitable for activating a refresh signal as many times as the refresh operation times code represents in response to the internal refresh command signal and the refresh operation times code; and
a refresh controller suitable for controlling rows of a cell array to be sequentially refreshed when the refresh signal is activated.

13. The memory device of claim 12, further comprising:
an end signal generator suitable for generating a refresh end signal representing that the refresh operations are performed as many times as the refresh operation times code represents; and
a transfer circuit suitable for transferring the refresh end signal to an exterior device

14. The memory device of claim 13, wherein the decoder further generates an internal refresh operation stop command signal, and
the refresh signal generator does not activate the refresh signal while the internal refresh operation stop command signal is activated.

15. The memory device of claim 14, wherein the refresh signal generator includes:
a periodic signal generation unit suitable for periodically activating the refresh signal from a moment when the internal refresh command signal is activated to a moment when a stop signal is activated;
a counting unit suitable for counting the number of times that the refresh signal is activated to generate a counting code;
a comparison unit suitable for comparing the counting code with the refresh operation times code to generate a preli inary stop signal; and
a stop signal generation unit suitable for activating the stop signal when at least one between the preliminary stop signal and the internal refresh operation stop command signal is activating.

16. The memory device of claim 15, wherein the end signal generator includes:
a delay unit suitable for generating a delayed refresh signal; and
an activating unit suitable for activating the refresh end signal when the delayed refresh signal and the stop signal are activated.

17. The memory device of claim 15, wherein the counting unit is initialized in response to an activating of the internal refresh command signal.
